(19) United States
(12) Patent Application Publication
(10) Pub. No.: US 2019/0348466 A1
(43) Pub. Date: Nov. 14, 2019

(54) AMBIPOLAR LAYER BASED ACCESS TRANSISTORS FOR MEMORY APPLICATIONS AND METHODS OF FABRICATION

(71) Applicant: Intel Corporation, Santa Clara, CA (US)

(72) Inventors: Ravi PILLARISETTY, Portland, OR (US); Prashant MAJHI, San Jose, CA (US); Elijah V. KARPOV, Portland, OR (US); Niloy MUKHERJEE, Portland, OR (US)

(21) Appl. No.: 16/462,514

(22) PCT Filed: Dec. 30, 2016
(86) PCT No.: PCT/US2016/069477

§ 371 Date: May 20, 2019

(51) Int. Cl. H01L 27/24; H01L 29/24; H01L 29/417; H01L 29/786; H01L 45/00; H01L 29/66; H01L 27/28; H01L 51/00; H01L 51/05

(52) U.S. Cl. CPC H01L 27/2436; H01L 51/0055; H01L 29/24; H01L 29/41733; H01L 29/78681; H01L 29/78696; H01L 45/08; H01L 45/1233; H01L 45/1253; H01L 45/146; H01L 29/66969; H01L 45/1675; H01L 27/283; H01L 27/285; H01L 51/0048; H01L 51/0558; H01L 27/2463

(57) ABSTRACT

A 1T-1R memory cell includes a transistor structure where an ambipolar layer is disposed on an insulator layer formed on a substrate. The transistor further includes a gate dielectric layer that is disposed on the ambipolar layer and a gate electrode disposed on the gate dielectric layer. A source region and a drain region are disposed on the ambipolar layer. The source region is separated from the drain region by the gate electrode. A source contact is disposed on the source region and a drain contact disposed on the drain region. The 1T-1R cell further includes a memory device that is disposed above the drain contact of the transistor. The memory device belongs to a class of memory devices that is based on resistive switching.

### TECHNICAL FIELD

Embodiments of the invention are in the field of integrated circuit fabrication and, in particular, ambipolar layer based transistors for memory applications and their methods of fabrication.

### BACKGROUND

For the past several decades, the scaling of features in integrated circuits has been a driving force behind an ever-growing semiconductor industry. Scaling to smaller and smaller features enables increased densities of functional units on the limited real estate of semiconductor chips. For example, shrinking transistor size allows for the incorporation of an increased number of memory devices on a chip, lending to the fabrication of products with increased functionality. The drive for ever-more functionality, however, is not without issue. It has become increasingly significant to rely heavily on innovative fabrication techniques to meet the exceedingly tight tolerance requirements imposed by scaling.

Non-volatile embedded resistive memory integrated with transistors (1T-1R), for example, on-chip embedded memory with non-volatility can enable energy and computational efficiency. Typically, a 1T-1R cell includes a transistor whose drain terminal is connected in series with a memory device. By biasing the transistor and the memory device appropriately, the resistance state of the memory device is toggled between high resistance state and low resistance state or vice versa enabling memory operation. However, inherent voltage losses due to dedicated channel type in single MOS transistors creates inefficiencies during 1T-1R operations. Such inefficiencies can present formidable roadblocks to commercialization of this technology as devices continue to scale in size as well as with respect to voltage and current requirements. Thus, furthering development in the areas of integrating novel transistors that overcome limitations imposed by dedicated single MOS transistors is an integral part of the non-volatile memory roadmap.

### BRIEF DESCRIPTION OF THE DRAWINGS

FIG. 1 illustrates a cross-sectional view of a transistor with an ambipolar layer and a resistive random access memory device formed on the drain contact of the transistor.

FIGS. 2A-2I illustrate cross-sectional views representing various operations in a method of fabricating a transistor with an ambipolar layer and an RRAM coupled to the drain of the transistor in accordance with embodiments of the present invention.

FIG. 2A illustrates a cross-sectional view of an ambipolar formed on an insulator layer formed above a substrate.

FIG. 2B illustrates the structure of FIG. 2A following the formation of a gate dielectric layer on the ambipolar layer and a gate electrode on the gate dielectric layer FIG. 2A illustrates a conductive interconnect surrounded by a first dielectric layer.

FIG. 2C illustrates the structure of FIG. 2B following the deposition of a dielectric layer,

FIG. 2D illustrates the structure of FIG. 2C following the formation of a drain contact in the drain region.

FIG. 2E illustrates the structure of FIG. 2D following the deposition of various materials layers to form an RRAM device on the drain contact.

FIG. 2F illustrates the structure of FIG. 2E following the formation of an RRAM device on the drain contact.

FIG. 2G illustrates the structure of FIG. 2F following the deposition of a second dielectric layer and a planarization process.

FIG. 2H illustrates the structure of FIG. 2G following the formation of a contact on the RRAM device.

FIG. 2I illustrates the structure of FIG. 2H following the formation of a source contact on the source region and a gate contact on the gate electrode of the transistor. FIG. 3H

FIG. 3A-3D Illustrates an ambipolar layer based transistor fabricated by a replacement gate process in an accordance with an embodiment of the present invention.

FIG. 3A illustrates the structure of FIG. 2C following an extended planarization process that exposes the hardmask and a subsequent process to remove the hardmask and the dummy gate stack.

FIG. 3B illustrates the structure of FIG. 3A following a deposition of a functional gate dielectric layer and a functional gate electrode.

FIG. 3C illustrates the structure of FIG. 3B following the deposition of an interlayer dielectric film (ILD) followed by the formation of source contact, a drain contact.

FIG. 3D illustrates the structure of FIG. 3C following the process operations described in connection with FIGS. 2E-2I to form an RRAM device, dielectric spacers, a contact electrode, a gate contact and a source electrode.

FIG. 4A-4C illustrate various biasing schemes on the source region, on the gate electrode, and on the RRAM top electrode to cycle the RRAM device and associated current-voltage traces of the RRAM device resulting from such biasing.

FIG. 4A illustrates biasing conditions to perform a RESET event in the RRAM device and associated current-voltage trace.

FIG. 4B illustrates biasing conditions to perform a SET event n the RRAM device and associated current-voltage trace.

FIG. 4C illustrates biasing conditions to perform a READ event in the RRAM device and associated current-voltage trace.

FIG. 5 illustrates a block diagram of an electronic system, in accordance with embodiments of the present invention.

FIG. 6 illustrates a computing device in accordance with embodiments of the present invention.

### DESCRIPTION OF THE EMBODIMENTS

An ambipolar layer based access transistor for memory applications and their methods of fabrication are described. In the following description, numerous specific details are set forth, such as novel structural schemes and detailed fabrication methods in order to provide a thorough understanding of embodiments of the present invention. It will be apparent to one skilled in the art that embodiments of the present invention may be practiced without these specific details. In other instances, well-known features, such as transistor operations and switching operations associated with embedded memory, are described in lesser detail in order to not unnecessarily obscure embodiments of the present invention. Furthermore, it is to be understood that the various embodiments shown in the Figures are illustrative representations and are not necessarily drawn to scale.

Integrating a memory array with low voltage logic circuitry, such as logic circuitry operational at a voltage less than or equal to 1 Volt, may be advantageous since it enables higher operation speeds compared to having physically separate logic and memory chips, As transistor operating voltages are scaled down in an effort to become energy efficient, a memory device that is connected in series with a transistor, to form a 1T-1R cell, is also required to function at lower voltages and currents. A 1T-1R cell typically utilizes a conventional metal oxide semiconductor (MOS) transistor. By appropriately biasing the gate, source and grain terminals of the MOS transistor, the resistance state of the memory device is toggled between high resistance state and low resistance state or vice versa, in a process known as resistance switching. By switching direction of the current flow through the transistor and the memory cell resistance switching is accomplished in a memory device. This in turn is accomplished by changing the bias on the respective terminals of the 1T-1R cell. Depending on the biasing condition the memory device is sometimes effectively connected to the drain end of a transistor and at other times connected to the source end. When the memory device is connected to the source end of the transistor the 1T-1R cell is said to be in a source follower configuration. In a source follower configuration, the gate to source voltage, V_{GS}, is effectively decreased from the power supply voltage because of the presence of the load resistor. Reduction in V_{GS}, therefore, reduces the effective transistor drive current, I_{D}. In the non-source follower configuration, the gate to source voltage, V_{GS}, is the same as the power supply voltage as there is no load in series at the source terminal. As a result, an asymmetry in current in the 1T-R cell results when the memory device is cycled. Typically, since resistance changes in a memory device are voltage driven during one part of the switching cycle and current driven in another, reduction in current during cycling is highly undesirable. One way to mitigate this effect is to increase the power supply voltage, V_{cc}, of the transistor during a portion of the cycling until that the current threshold required to switch the memory device is met. However, increasing V_{cc}, also increases power requirement. For a given channel type (N or P), the asymmetry in the gate to source voltage, V_{GS}, during resistance switching is a fundamental problem in both NMOS or PMOS transistors. Because of the fixed majority charge carrier in each MOS type, it is not possible to reverse the voltage polarity on the gate to avoid a source follower configuration during a portion of the switching cycle. However, by implementing a 2-dimensional (2D) material such as an ambipolar layer, a transistor channel may be able to conduct both electrons and holes enabling direction of the current flow in the 1T-1R cell to be reversed in a single switching cycle. In one such transistor, the sign of the majority carrier can be dictated by changing the polarity of the applied voltage on the gate and on the drain terminals of the transistor as will be discussed further below. A 1T-1R cell fashioned with one such transistor including an ambipolar layer may be able to operate in non-source follower mode during the entire switching cycle with no appreciable reduction in current flow. Adverse effects arising from reduction in available current flow in the 1T-1R cell may be avoided.

In accordance with embodiments of the present invention, a 1T-1R memory cell includes a transistor structure where an ambipolar layer is disposed on an insulator layer formed on a substrate. The ambipolar layer may include a material such as but not limited to transition metal dichalcogenide (TMDC) layer, a carbon nanotube (CNT) or a pentacene layer. Similar to a traditional FET, the transistor further includes a gate dielectric layer that is disposed on the ambipolar layer and a gate electrode disposed on the gate dielectric layer. A source region and a drain region are disposed on the ambipolar layer. The source region is separated from the drain region by the gate electrode. A source contact is disposed on the source region and a drain contact disposed on the drain region. In an embodiment, the source contact and the drain contact include an adhesion layer that can also improve the contact resistance and improve carrier conduction by reducing the Schottky barrier height. A transistor fashioned from an ambipolar layer exhibits several properties that makes it highly desirable for low power transistor applications, namely (a) large ON-OFF current ratio (>10⁸) resulting in significantly reduced off-state leakage and (b) lack of mobility dependence at high gate fields.

The 1T-1R cell further includes a memory device that is disposed above the drain contact of the transistor. The memory device belongs to a class of memory devices that is based on resistive switching. That is, the state of the memory device corresponds to state where the device is in a high resistance state or a low resistance state. Some examples of memory devices that exhibit resistive switching include metal oxide resistive random access memory (RRAM), conductive bridge resistive random access memory (CBRAM) and spin transfer torque memory (STTM). Additionally, depending on embodiments, the memory device may be directly disposed on the drain contact or connected to the drain contact by a series of copper interconnects having negligible line resistance.

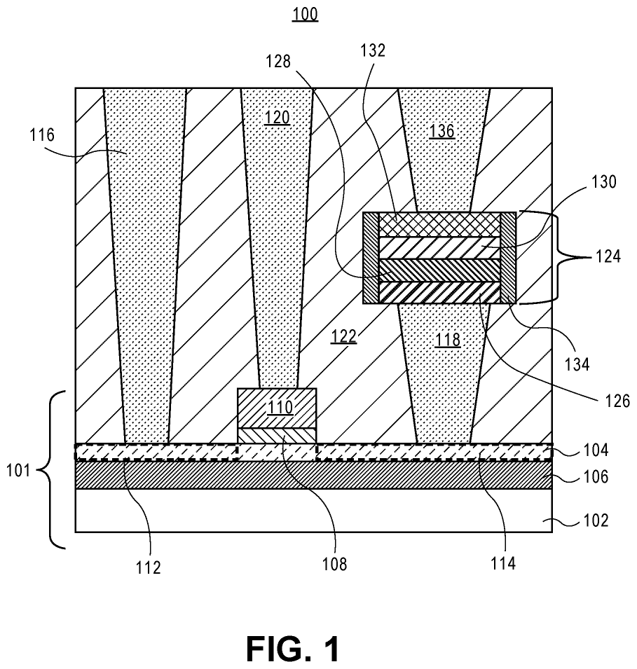

FIG. 1 illustrates a 1T-1R cell 100 in accordance with an embodiment of the present invention. The 1T-1R cell 100 includes a transistor 101 disposed on a semiconductor substrate 102 and a memory device 124 coupled with the transistor 101. The transistor 101 includes an ambipolar layer 104 disposed on an insulator layer 106. The insulator layer 106 is disposed on the substrate 102. A portion of the ambipolar layer 104 forms a channel of the device. A gate dielectric layer 108 is disposed on the channel portion of the ambipolar layer 104. A gate electrode 110 is disposed on the gate dielectric layer 108. A source region 112 and a drain region 114 are disposed on the ambipolar layer 104. The source 112 region is separated from the drain region 114 by the gate electrode 110. A source contact 116 is disposed on the ambipolar layer 104 in the source region 112 and a drain contact 118 is disposed on the ambipolar layer 104 in the drain region 114. A gate contact 120 is disposed on the gate electrode 110.

The ambipolar layer 104 may include a material such as but not limited to transition metal dichalcogenide (TMDC) layer, a carbon nanotube (CNT) or a pentacene layer. In an embodiment, the ambipolar layer 104 is a TMDC layer. In one such embodiment, the TMDC layer has a chemical composition, MX₂, where M is a transition metal and X is a chalcogen. In an embodiment, the transition metal, M, is selected from a group consisting of molybdenum, tungsten and chromium, and the chalcogen, X, is selected from a group consisting of sulfur, selenium and tellurium. In an embodiment the TMDC layer is WSe₂. The TMDC is typically an atomically uniform film having a thickness ranging between 0.2-2 nm. In an embodiment, the TMDC layer has a thickness that is 0.5 nm. The TMDC layer has a direct bandgap that is at least 1.8 eV and facilitates transport of both holes and electrons. Depending on the material composition of the TMDC layer, the electron and hole mobility can range from approximately 30-200 cm²V⁻¹s⁻¹. Such a range is within an order of magnitude of the maximum electron and hole mobility in silicon.

In an embodiment, the gate dielectric layer 108 includes a material such as, but not limited to silicon oxide, silicon dioxide (SiO₂), silicon nitride or a high-k dielectric material. The high-k dielectric material may include oxides such as but not limited to hafnium oxide, hafnium silicon oxide, lanthanum oxide, lanthanum aluminum oxide, zirconium oxide, zirconium silicon oxide, tantalum oxide or titanium oxide. Another example of TMDC compatible gate dielectric layer 108 includes a material such as hexagonal boron nitride. In an embodiment, the gate dielectric layer 108 has a thickness that ranges between 0.5 nm-2 nm.

In an embodiment, the transistor 101 includes a gate electrode 110 with a workfunction in the range of 3.8 eV-4.5 eV. Similar to traditional MOSFET, the work function of gate electrode 110 in transistor 101 is tuned to optimize threshold voltage. For an ambipolar layer 104, gate workfunction optimization includes having to optimize for both electron and hole transport to accomplish current flow in directions from drain to source and vice versa. In an embodiment, the gate electrode 110 includes metals such as palladium or gold or a metal alloy such as TiN. in some implementations, the gate electrode 110 may consist of a stack of two or more conductive layers, where a first conductive layer that is directly disposed on the ambipolar layer 104 sets the workfunction of the gate electrode 110, and the remaining one or more conductive layers include fill layers.

In an embodiment, the source contact 116 and drain contact 118 includes a material such as but not limited to tungsten, titanium, gold, scandium or graphene. In some implementations, the source contact 116 and drain contact 118 may include a contact adhesion layer. In some implementations, the contact adhesion layer is chosen to minimize barrier height for optimizing electron and hole conduction between source and drain contacts 116 and 118 and the source and drain regions 112 and 114, respectively, of the ambipolar layer 104. Examples of such adhesion layers include Ti or Ni. The thickness of the adhesion layer can range from 3-10 nm.

In an embodiment, the substrate 102 includes a semiconductor material such as but not limited to silicon, silicon germanium (Ge) or silicon carbide (SiC). In an embodiment, insulator layer 106 includes a material such as, but not limited to silicon dioxide (SiO₂), carbon doped oxide (CDO), silicon nitride. In an embodiment, the insulator layer 106 has a thickness in the range of 30 nm-200 nm. In an embodiment, the dielectric layer 122 includes a material such as but not limited to silicon dioxide, silicon carbide or cabon-doped silicon oxide. A memory device 124 is disposed on the drain contact 118 of the transistor 101. The memory device may include a metal oxide resistive random access memory (RRAM) element, a conductive bridge resistive random access memory (CBRAM) element or a spin transfer torque memory (STTM) element, In an embodiment, the memory device 124 is a resistive random access memory (RRAM) device as is illustrated in FIG. 1. In one such embodiment, the RRAM device includes a bottom electrode 126 disposed on the drain contact 118, a metal oxide switching layer 128 disposed above the bottom electrode 126 and a top electrode 132 disposed above the switching layer 128. In an embodiment, the RRAM device incudes an oxygen exchange layer 130. The oxygen exchange layer 130 may be disposed between the bottom electrode 126 and the metal oxide switching layer 128, as is illustrated in FIG. 1, or between the metal oxide switching layer 128 and the top electrode 132. in a different embodiment. In an embodiment, a dielectric spacer 134 is disposed laterally adjacent and on sidewalls of the RRAM device and on the dielectric layer 122. The dielectric spacer 116 extends from the bottom of the bottom electrode layer 126 to an upper most surface of the top electrode 132 and is designed to prevent oxidation of the oxygen exchange layer 130. A contact electrode 136 is disposed in the dielectric layer 122 and on a portion of the top electrode 132. The RRAM device may have a width that is larger or smaller than the width of the drain contact 118.

In an embodiment, the bottom electrode 126 includes a material such as but not limited to titanium nitride, tantalum, tantalum nitride, tungsten or ruthenium. In an embodiment, the bottom electrode 126 has a thickness in the range of 40 to 100 nanometers (nm). Typically for RRAM applications the composition and thickness of the bottom electrode 126 are tuned to meet specific device attributes such as series resistance, programming voltage and current. In an embodiment, a monolayer portion of the bottom electrode 126 at an interface between the bottom electrode 126 and the metal oxide switching layer 128 is oxidized but remains conductive. In one such embodiment, the bottom electrode 126 includes tungsten or ruthenium.

In an embodiment, the metal oxide switching layer 128 is composed of a metal (M), such as but not limited to, hafnium, tantalum or titanium. In the case of titanium or hafnium, or tantalum with an oxidation state +4, the metal oxide switching layer 128 has a chemical composition, MO_{X}, where O is oxygen and X is or is substantially close to 2. In the case of tantalum with an oxidation state +5, the metal oxide switching layer 128 has a chemical composition, M₂Oₓ, where O is oxygen and X is or is substantially close to 5. In an embodiment, the metal oxide layer 128 has a thickness in the range of 1-5 nm.

In an embodiment, the oxygen exchange layer 130 acts as a source of oxygen vacancy or as a sink for O²⁻. In an embodiment the oxygen exchange layer 130 is composed of a metal such as but not limited to, hafnium, tantalum or titanium. In an embodiment, oxygen exchange layer 130 has a thickness in the range of 5-20 nm. In an embodiment, the thickness of the oxygen exchange layer 130 is at least twice the thickness of the metal oxide switching layer 126. In another embodiment, the thickness of the oxygen exchange layer 130 is at least twice the thickness of the metal oxide switching layer 128.

In an embodiment, the top electrode 132 is composed of a material such as, but not limited to, titanium nitride, tantalum nitride, tungsten and ruthenium. In an embodiment, the bottom electrode 126 and the top electrode 132 are composed of the same material. In an embodiment, the top electrode has a thickness approximately in the range of 30 to 100 nm. In an embodiment, the composition and thickness of the top electrode 132 are tuned to meet specific device attributes such as series resistance, programming voltage and current.

In an embodiment, the dielectric spacer 134 may be any suitable dielectric material such as but not limited to carbon doped silicon nitride or silicon nitride. Typically, a non-oxygen-containing material is preferred for the dielectric spacer 134 to minimize oxidation of sidewalls of the oxygen exchange layer 130. In an embodiment, the dielectric spacer 114 has a thickness that ranges from 30-60 nm.

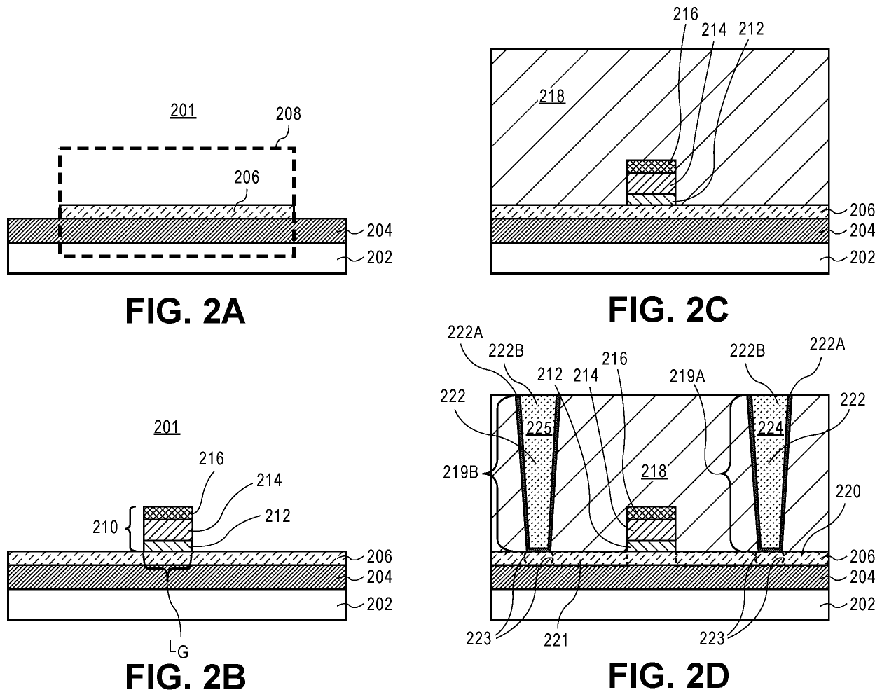

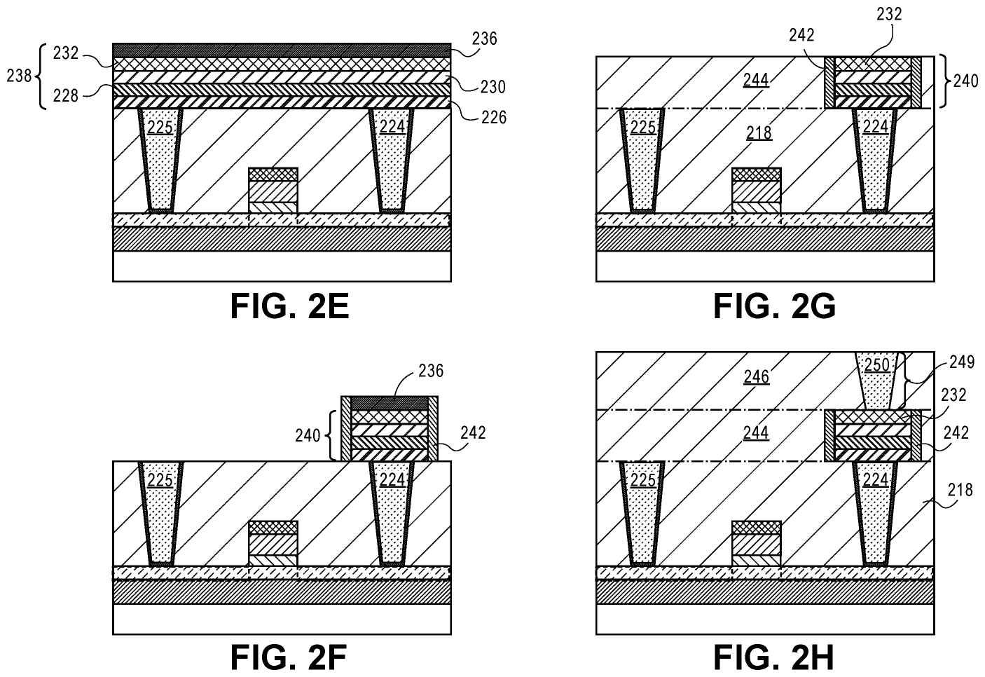

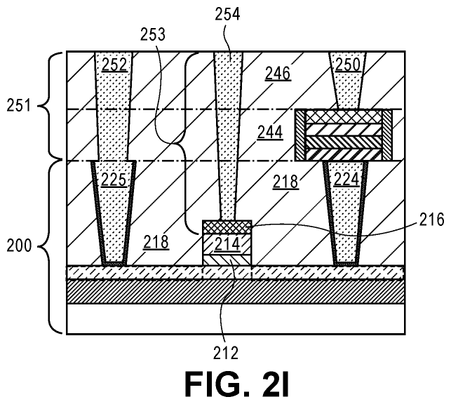

FIGS. 2A-2I illustrate cross-sectional views representing various operations in a method of fabricating a transistor 200 with an ambipolar layer 206 and an RRAM device 240 coupled to the drain contact 224 of the transistor 200 in accordance with embodiments of the present invention.

FIG. 2A illustrates a cross-sectional view of a patterned ambipolar layer 206 formed on an insulator layer 204 formed above a substrate 202. In an embodiment, an insulator layer 204 is formed on the substrate 202. Thee insulator layer 204 includes a material such as but not limited to silicon dioxide, silicon carbide or cabon-doped silicon oxide. In an embodiment, the insulator layer 204 is blanket deposited on the substrate 202 by a chemical vapor deposition (CVD) process or plasma enhanced chemical vapor deposition (PECVD) process. In an embodiment, the thickness of the insulator layer 204 ranges from 50-200 nm.

In an embodiment, the ambipolar layer 206 is deposited on the insulator layer 204. In an embodiment, the ambipolar layer 206 includes a material such as a but not limited to transition metal dichalcogenide (TMDC), a carbon nanotube or a pentacene. In one specific embodiment, the ambipolar layer 206 is a TMDC layer. In one such embodiment, the TMDC layer has a chemical composition, MX₂, where M is a transition metal and X is a chalcogen. In an embodiment, the transition metal, M, is selected from a group consisting of molybdenum, tungsten and chromium, and the chalcogen, X, is selected from a group consisting of sulfur, selenium and tellurium. In an embodiment the TMDC layer is WSe₂. In an embodiment, ambipolar layer 206 is deposited by a process such as an atomic layer deposition (ALD) process, a thermally assisted growth process, or an exfoliation process that is well known in the art. In an embodiment, for the purposes of meeting operational requirements of a 1T1R cell, the ambipolar layer 206 is highly uniform and atomically thin. In an embodiment, the ambipolar layer 206 has a thickness that ranges between 0.5 nm-2 nm. The uniformity of such thin layers dictates the quality of the accumulation or depletion regions that will be formed during transistor operation.

The transistor 200 is built on a foundation of the ambipolar layer 206. To define a source, a drain and a gate region of the transistor 200, the ambipolar layer 206 is first patterned and then subsequently etched as is depicted by the dashed box 208 in the illustration of FIG. 2A. In other embodiments, desired portions of the ambipolar layer 206 where the transistor is to be fabricated is formed by masking a region and subsequently treating the exposed areas to an O2 containing plasma ash process. The O2 plasma ash process is an example of an oxidizing process that can convert the exposed portions of ambipolar layer 206 into a dielectric layer. Such a process may avoid etch and exposure of ultrathin sidewalk of the ambipolar layer 206.

FIG. 2B illustrates the structure of FIG. 2A following the formation of a gate stack 210 on the ambipolar layer 206. In an embodiment, the gate stack 210 includes a gate dielectric layer 212 and a gate electrode layer 214. In an embodiment, the gate dielectric layer 212 includes a material such as gate dielectric layer 108. In an embodiment, a gate dielectric layer 212 having a thickness ranging from 05 nm-2 nm, is formed on the ambipolar layer 206 using an atomic layer deposition (ALD) technique. In an embodiment, the gate electrode layer 214 includes a layer such a gate electrode 110 and is formed on the surface of the gate dielectric layer 212 using a PVD or an ALD process. In an embodiment, thickness of the gate electrode layer 214 ranges from 20-100 nm.

In an embodiment, hardmask layer 216 is formed on the gate electrode layer 214 to enable patterning of the gate stack 210. In an embodiment, the hardmask layer 216 includes a material such as silicon nitride, silicon oxynitride or carbon doped silicon nitride as is blanket deposited on the gate electrode layer 214. In an embodiment, the thickness of the hardmask layer 216 ranges from 10-50 nm. In an embodiment, a photoresist pattern is formed on the hardmask layer 216. In an embodiment, the hardmask layer 216 and the gate stack 210 is subtractively etched by a plasma etch process. A gate electrode layer 214 having a thickness of approximately 30 nm or less may also be patterned using a wet etch technique. In an embodiment, the gate length, L_{G}, of the gate stack 210 ranges from 10-30 nm.

FIG. 2C illustrates the structure of FIG. 2B following the deposition and planarization of a dielectric layer 218. In an embodiment, a dielectric layer 218 is blanket deposited using a PECVD process. In an embodiment, the dielectric layer 218 is deposited to a thickness of at least 2.5 times the combined thickness of the patterned gate stack 210 and the hardmask layer 216 to provide sufficient material to form a planarized dielectric layer 218. In an embodiment, the planarization process is a chemical mechanical polish (CMP) process.

FIG. 2D illustrates the structure of FIG. 2C following the formation of a drain contact 224 in the dielectric layer 218 in the drain region 220 and the formation of a source contact 225 in the dielectric layer 218 in the source region 221. In an embodiment, a drain opening 219A and a source opening 219B are formed in the dielectric layer 218 by a combination of a plasma etch process followed by a wet etch process. The wet etch process exposes the ambipolar layer 206 and may prevent damage to the ambipolar layer 206. A contact material 222 is deposited on the surface of the ambipolar layer 206 and fills the drain opening 219A and the source opening 219B. In an embodiment, the contact material may include an adhesion layer 222A and a conductive cap layer 222B as is illustrated in FIG. 2D. The adhesion layer 222A is first deposited on surface of the ambipolar layer 206, and the conductive cap layer 22213 is deposited on the adhesion layer 222A. The adhesion layer 222A may include a material such as Ti, Ni, Sc or graphene. A strong Vander Walls interaction between the adhesion layer 222A and the uppermost surface of the ambipolar layer 206 can help form a robust contact. In an embodiment, the adhesion layer 222A forms a Schottky or an ohmic contact with the ambipolar layer 206 to minimize contact resistance between the ambipolar layer 206 and an RRAM device that will eventually be formed on the drain contact 224. The conductive cap layer includes a material having a low electrical resistance such as tungsten, ruthenium or copper. By minimizing the overall contact resistance of the source contact 225 and the drain contact 224, the amount of current that can flow through the RRAM device can be optimized. After deposition of the adhesion layer 222A and the conductive cap 222 a planarization process may be carried out to form the drain contact 224 and source contact 225. In some instances, a forming gas anneal employing a H2/N2 mixture (5% H2/95% N2) may be carried out at 200-250 degrees C. to improve the interface between the drain and source contacts 224 and 225, respectively and the ambipolar layer 206.

In a different embodiment, the plasma etch process that forms the drain opening 219A in the drain region 220 and the source opening 219B in the source region 221 also etches through the ambipolar layer 206 (denoted by dashed lines 223). In such an instance, the contact material 222 is formed adjacent to the exposed sidewalk of the ultrathin ambipolar layer 206. Contacts formed adjacent to the sidewalls of the ambipolar layer 206 may offer electrostatic advantages such as enhanced carrier injection into the drain and source regions 220 and 221, respectively. In yet another embodiment, a wet etch process is carried out after the plasma etch process etches through the ambipolar layer 206 in each of the drain and source openings 219A and 219B, respectively. in one such embodiment, the wet etch process widens the drain and source openings 219A and 219B, respectively, and exposes a portion of an uppermost surface of the ambipolar layer 206 in the drain and source openings 219A and 219B, respectively. The contact material 222 which is subsequently deposited in the drain opening 219A and source opening 2198. has portions that are in contact with the sidewalls and portions that are in contact with the uppermost surface of the ambipolar layer 206 in in the drain opening 219A and source opening 219B.

The fabrication of a memory device on the drain contact 224 is described next. In an embodiment, the memory device is an RRAM device which includes a switching layer that is a metal oxide.

FIG. 2E illustrates the structure of FIG. 2D following the deposition of an RRAM material layer stack 238 on the drain contact 224 and on the uppermost surface of the dielectric layer 218. In an embodiment, the deposition of the RRAM material layer stack 238 includes a sequential deposition of a bottom electrode layer 226, a metal oxide switching layer 228, an oxygen exchange layer 230 and a top electrode layer 232 on the uppermost surface of the drain contact 222 and on the uppermost surface of the dielectric layer 218. The top electrode is capped by a dielectric hardmask layer 236.

In an embodiment, the bottom electrode layer 226 is a material having a composition and a thickness similar to the material composition and thickness of the bottom electrode layer 126. In an embodiment the bottom electrode layer 226 includes a material that is deposited by a physical vapor deposition (PVD) process. The PVD deposition method may further include a pre-deposition in-situ sputter cleans to first remove any oxide residue from an uppermost surface of the drain contact 224. in an embodiment, the sputter cleans process may include a gas containing Ar to energetically bombard the upper most surface of the drain contact 224 in order to remove any native oxide.

The metal oxide switching layer 228 is formed on the bottom electrode layer 226. In an embodiment, the metal oxide switching layer 228 is composed of a material having a composition and a thickness similar to the material composition and thickness of the metal oxide switching material 128. In an embodiment, the metal oxide switching layer 228 is formed using an ALD process. The ALD process may be characterized by a slow and a highly controlled metal oxide deposition rate. The ALD process may also be highly uniform (e.g., approximately 0.1 nm level variation). in an embodiment, a pre-clean of the surface of the bottom electrode layer 226 is performed immediately prior to deposition of the metal oxide switching layer 228. In another embodiment, the metal oxide switching layer 228 is formed using a PVD process. In an embodiment, a pre-clean of the surface of the bottom electrode layer 226 is performed using an Ar sputter clean immediately prior to deposition of the metal oxide switching layer 228.

The oxygen exchange layer 230 is formed on the metal oxide switching layer 228. In an embodiment, the oxygen exchange layer 230 is a material having a composition and a thickness similar to the material composition and thickness of the oxygen exchange material 130. In an embodiment, the oxygen exchange layer 230 is formed using a PVD process. In one such embodiment, the metal oxide switching layer 228 and the oxygen exchange layer 230 are deposited sequentially in a same chamber or in a same tool without breaking vacuum.

The top electrode layer 232 is formed on the oxygen exchange material 230. In an embodiment, the top electrode layer 232 is a material having a composition and a thickness similar to the material composition and thickness of the top electrode 132. In an embodiment, the top electrode layer 232 is formed using a PVD process. In an embodiment, the top electrode layer 232 and the oxygen exchange layer 230 are deposited sequentially in a same chamber or in a same tool without breaking vacuum. By doing so, the oxygen exchange layer 230 does not become oxidized. In an embodiment the top electrode layer 232 has a same composition as the bottom electrode layer 226. The dielectric hardmask layer 236 is blanket deposited on the top electrode 232 using a PECVD process. The dielectric hardmask layer 236 may include a silicon nitride or a carbon doped silicon nitride layer.

FIG. 2F illustrates the structure of FIG. 2E following the formation of an RRAM device 240 on the drain contact 224 and a formation of a dielectric spacer 242. surrounding the RRAM device 240. In an embodiment, the dielectric hardmask layer 236 and the RRAM material layer stack 238 are patterned by a plasma etch process to form a patterned dielectric hardmask layer 236 and an RRAM device 240. Subsequently, a dielectric spacer 242 is blanket deposited on the patterned dielectric hardmask layer 236, on sidewalk of the RRAM device 240 and on the dielectric layer 218 and then etched back to form a dielectric spacer 242. In an embodiment, deposition of the dielectric spacer layer 242 is performed immediately post formation of the RRAM device 240, but prior to breaking vacuum in the same tool or chamber used for the etch process. Such a procedure, known in the art as in-situ deposition, may hermetically seal the device and potentially decrease oxidation of the perimeter of the sensitive oxygen exchange layer 230. In an embodiment, the dielectric spacer layer is a material such as, but not limited to, silicon nitride, silicon carbide, carbon-doped silicon nitride, or any suitable non-oxygen containing material, In an embodiment, the dielectric spacer layer has a thickness approximately in the range of 20-50 nm. In an embodiment, the dielectric spacer layer may be plasma etched to form dielectric spacer 242. The plasma etch process removes all of the dielectric spacer layer 242 from the uppermost surface of the hardmask layer 236 and from the uppermost surface of the dielectric layer 218.

FIG. 2G illustrates the structure of FIG. 2F following the deposition of a second dielectric layer 244 followed by a planarization process. The second dielectric layer 244 is blanket deposited on the memory device 240, on the dielectric spacer 242, on the first dielectric layer 218 and on the source contact 225. In an embodiment, the second dielectric layer 244 is compositionally similar to the dielectric layer 218. In an embodiment, the planarization process removes the excess portions of the second dielectric layer 244 deposited above the dielectric hardmask layer 236. The planarization process is further extended to remove the entire hardmask layer 236 and removes top portions of the top electrode 232. and top portions of the dielectric spacer 242. In an embodiment, the planarization process results in the second dielectric layer 244, the top electrode layer 232 and the dielectric spacer 242 having uppermost surfaces that are substantially coplanar as is illustrated in FIG. 2G.

FIG. 2H illustrates the structure of FIG. 2G following the formation of a contact electrode 250 on the RRAM device 240. In an embodiment, a third dielectric layer 246 is blanket deposited on the structure of FIG. 2G. An electrode opening 249 is formed in the third dielectric layer 246 and exposes a portion of the top electrode 232. A contact electrode 250 is formed by a contact electrode material deposition process and a planarization process. The contact electrode material may include a metal such as tungsten, ruthenium or copper. In an embodiment, a Ta liner is used to form a liner in the opening 249 prior to deposition of the contact electrode material.

FIG. 2I illustrates the structure of FIG. 2H following the formation of a source electrode 252 on the source contact 225 and the formation of a gate contact 254 on the gate electrode layer 214. In an embodiment, an opening 251 is formed in the third and second dielectric layers 246 and 244 respectively. The opening 251 exposes the source contact 225. The opening 251 may be filled with a contact electrode material such as tungsten, ruthenium or copper and then planarized to form a source electrode 252. Subsequently, a gate electrode opening 253 is formed in the dielectric layer 218, and in the second and third dielectric layers 244 and 246 respectively and in a portion of the hardmask layer 216 to expose the gate electrode layer 214. The gate electrode opening 253 may be filled with a metal such as tungsten and subsequently planarized. In a variation of the present embodiment, the gate contact 254 may be formed before the formation of the source electrode 252. In another embodiment, the source electrode 252, the contact electrode 250 and the gate contact 254 may be all formed at the same time.

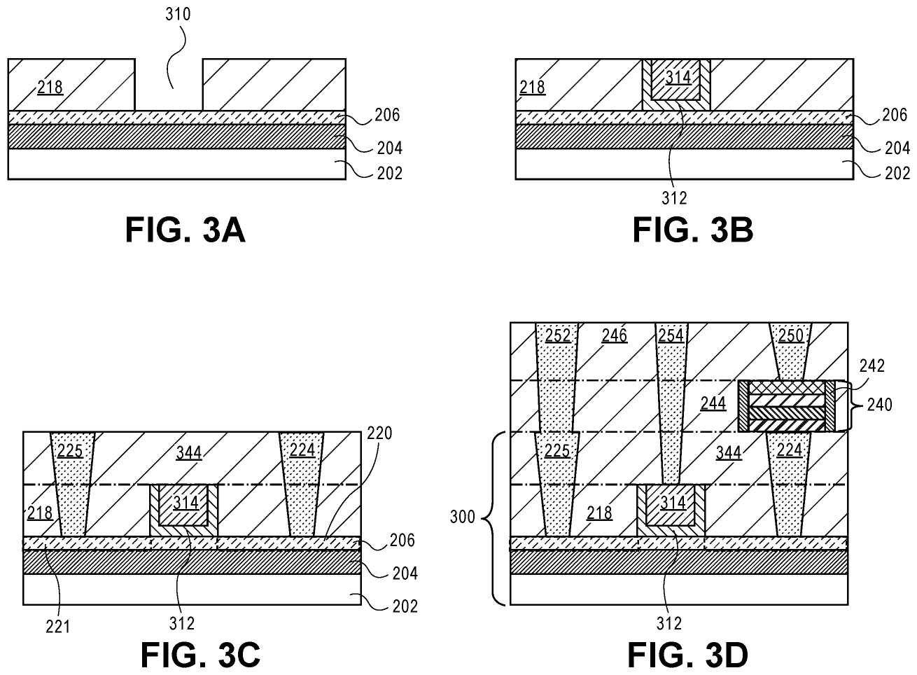

FIG. 3A-3D Illustrates an ambipolar layer based transistor 300 fabricated by a replacement gate process in an accordance with an embodiment of the present invention.

FIG. 3A illustrates the structure of FIG. 2C following an extended planarization process to expose the hardmask 216 and a subsequent etch process to remove the hardmask 216 and the gate stack 210. In an embodiment, the gate stack 210 is a replaceable dummy gate stack which includes a gate dielectric layer 212 that is silicon dioxide and a gate electrode layer 214 that is polysilicon. Removal of the gate stack 210 creates an opening 310.

FIG. 3B illustrates the structure of FIG. 3A following a deposition of a functional gate dielectric layer 312 and a functional gate electrode 314 followed by a planarization process. In an embodiment, the functional gate dielectric layer 312 and the functional gate electrode 314 include materials similar to the materials used to fabricate gate dielectric layer 108 and gate electrode 110, respectively. The functional gate dielectric layer 312 and the functional gate electrode 314 may be deposited by an ALD process to ensure conformal deposition in the opening 310. The excess functional gate dielectric layer 312 and the excess functional gate electrode 314 deposited over the uppermost surface of the dielectric layer 218 may be removed by a planarization process such as a CMP process.

FIG. 3C illustrates the structure of FIG. 3B following the deposition of an interlayer dielectric film (ILD) 344 followed by the formation of source contact 225, a drain contact 224 in the source region 221 and drain region 220. The materials and methods utilized to form source contact 225 and drain contact 224 are as described above.

FIG. 3D illustrates the structure of FIG. 3C following the process steps described in connection with FIGS. 2E-2I to form an RRAM device 240, dielectric spacers 242, a contact electrode 250, a gate contact 254 and a source electrode 252.

The various embodiments of the 1T-1R cell 100 typically undergo a high temperature anneal process at the end of the fabrication process. In an embodiment, annealing is carried out at temperatures in the range of 350 degrees C.-450 degrees C. and last for a time period ranging from 30-60 minutes. Annealing offers an additional advantage such as lowering the voltage required to “voltage-form” (or initialize) the RRAM device 240.

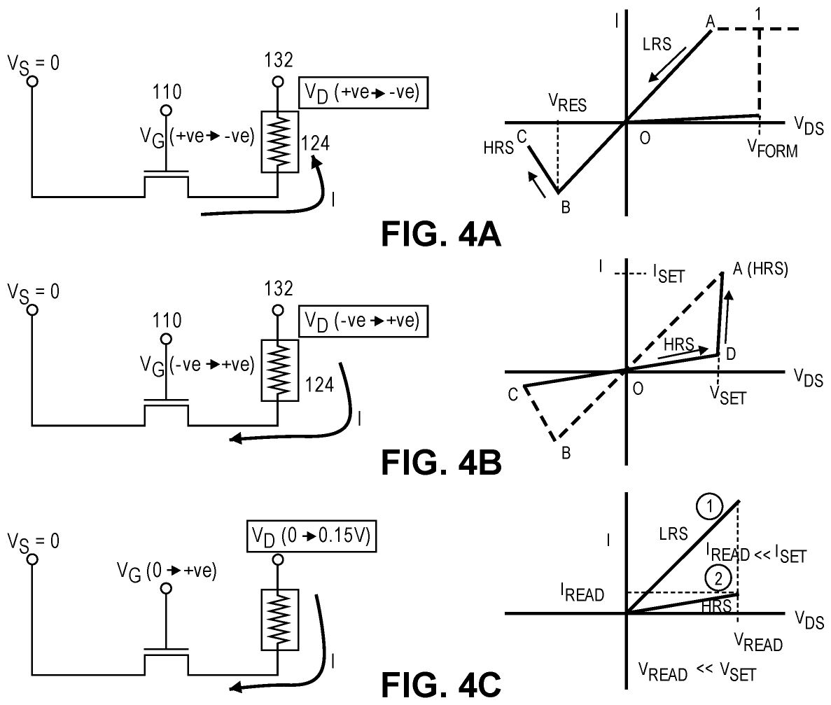

FIG. 4A-4C illustrate various biasing schemes on the source region 112, on the gate electrode 110, and on the RRAM top electrode 132 to cycle the RRAM device 124 and associated current-voltage traces of the RRAM device 124 resulting from such biasing. The operation of the 1T-1R circuit in the FIGS. 4A-4B highlights some advantages of ambipolar layer 104 in the 1T-1R cell 100.

FIG. 4A illustrates biasing conditions to perform a RESET event in the RRAM device 124 and the associated current voltage trace of the RRAM device 124. Referring to the I-V trace in FIG. 4A, at point A, the RRAM device 124 is in a low resistance state after having undergone a “forming event” (dashed line 1). The forming event is associated with the creation of a conductive filament in the metal oxide switching layer 128. Referring to the circuit diagram of the 1T-1R cell 100 in FIG. 4A, the source voltage, V_{S}, is set to ground or 0, and the voltage, V_{D}, on the top electrode 132, and the voltage, V_{G}, on the gate electrode 110 are slowly changed from a positive value to a negative value as indicated in the circuit diagram. The corresponding I-V_{DS} trace for the RRAM device 124 illustrates the current-voltage relationship during this portion of the switching cycle. From point A, the voltage V_{DS}, gradually decreases in magnitude to 0 (at point O) and then reverses polarity and increases in magnitude (from point O to point B). At point B, the voltage, V_{D}, on the top electrode 132 (with respect to the source), reaches a critical negative value, V_{RESET}. At point B, the gate voltage, V_{G}, is also negative with respect to the source. As the magnitude of the voltage, V_{D}, on the top electrode 132 continues to increase (point B to point C), the RRAM device 124 undergoes a transition from a low resistance state (LRS) at point B to a high resistance state (HRS) at point C. The transition from LRS to HRS is termed RESET. The direction of the current through the transistor changes when the “gate voltage”, V_{G}, “and” the top electrode voltage, V_{D}, change from a positive value to a negative value (around point O). It is to be appreciated that the polarity of the gate voltage and the polarity of the drain voltage must be in sync to enable current flow in the desired direction. The change in direction of the current (around point O) is made possible by the presence of the ambipolar layer 104 which enables electron and hole transport. The direction of the current shown in the circuit diagram in FIG. 4A represents the direction of hole transport during any moment from point O to point C. Typical SET voltages for an RRAM device 124 can range from 0.8V to 1.2V.

FIG. 4B illustrates biasing conditions to perform a SET event in the RRAM device 124 and the associated current voltage trace of the RRAM device 124. At point C the RRAM device 124 is in HRS state. Referring to the circuit diagram of the 1T-1R cell 100 in FIG. 4B, the source voltage, V_{S}, is set to ground or 0, and the voltage, V_{D}, on the top electrode 132, and the voltage, V_{G}, on the gate electrode 110 are slowly changed from a negative value to a positive value as indicated in the circuit diagram. The corresponding I-V_{DS} trace in the RRAM device 124 illustrates the current-voltage relationship during this portion of the switching cycle. From point C, the magnitude of the voltage V_{DS}, gradually decreases in magnitude to 0 (at point O) and then reverses polarity and increases in magnitude (from point O to point D). At point D, the voltage, V_{D}, (with respect to the source), on the top electrode 132 reaches a critical positive value, V_{SET}. At point D, the gate voltage, V_{G}, is also positive with respect to the source. As the magnitude of the voltage, V_{D}, on the top electrode 132. continues to increase (point D to point A), the RRAM device 124 undergoes a transition from HRS at point D to a LRS at point A. The transition from HRS to LRS is termed SET. The direction of the current through the transistor changes when the “gate voltage”, V_{G}, “and” the top electrode voltage, V_{D}, change from a negative value to a positive value (around point O). The change in direction in the current (about point O) is made possible by the presence of the ambipolar layer 104 which now enables hole transport in an opposite direction as compared to the direction indicated in FIG. 4A. The direction of the current shown in the circuit diagram in FIG. 4B represents the direction of hole transport during any moment from point O to point A. Typical SET voltages for an RRAM device 124 can range from 0.8-1.2V.

FIG. 4C represents the transistor biasing condition to perform a read event. The READ operation of a memory cell is often more important for memory applications that to SET or RESET. In practice, a memory cell is more often programmed into a certain state once but read back repeatedly. Typically read operation is performed over a voltage range of 0.1-0.2V. In one specific example a finite small positive voltage V_{D}, and V_{G}, are applied to the contact electrode and the gate electrode, respectively. The I-V plot in FIG. 4C, drawn at a magnified scale, illustrates current-voltage trace for two read events in the RRAM device 124. Read event 1 corresponds to reading of the RRAM device 124 in the LRS state and read event 2 corresponds to reading of the RRAM device 124 in the HRS state. The magnitude of the READ voltage is too small to cause any perturbation in the RRAM device 124 and does not enable a resistance change. The relative magnitude of the READ voltage and READ current is very small compared to the magnitude of the SET voltage and SET current.

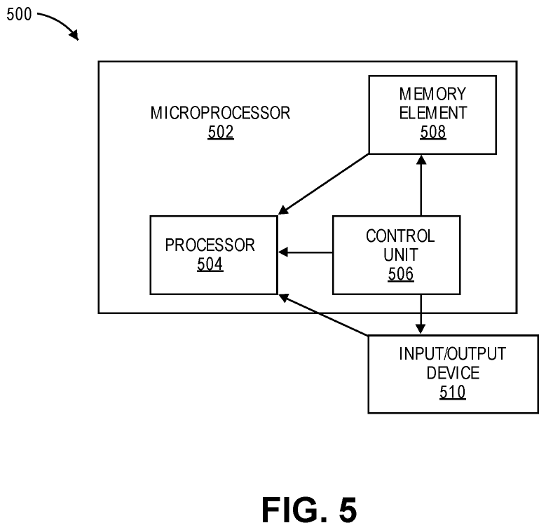

FIG. 5 illustrates a block diagram of an electronic system 500, in accordance with an embodiment of the present invention. The electronic system 500 can correspond to, for example, a portable system, a computer system, a process control system, or any other system that utilizes a processor and an associated memory. The electronic system 500 may include a microprocessor 502. (having a processor 504 and control unit 506), a memory device 124, transistor with an ambipolar layer 104 and an input/output device 530 (it is to be appreciated that the electronic system 500 may have a plurality of processors, control units, memory device units and/or input/output devices in various embodiments). In one embodiment, the electronic system 500 has a set of instructions that define operations which are to be performed on data by the processor 504, as well as, other transactions between the processor 504, the memory device 508, and the input/output device 510. The control unit 506 coordinates the operations of the processor 504, the memory device 508 and the input/output device 510 by cycling through a set of operations that cause instructions to be retrieved from the memory device 508 and executed. The memory device 508 can include a memory device having a conductive oxide and electrode stack as described in the present description. In an embodiment, the memory device 508 is embedded in the microprocessor 502, as depicted in FIG. 5. In an embodiment, the processor 504, or another component of electronic system 500, includes an array of RRAM devices 124.

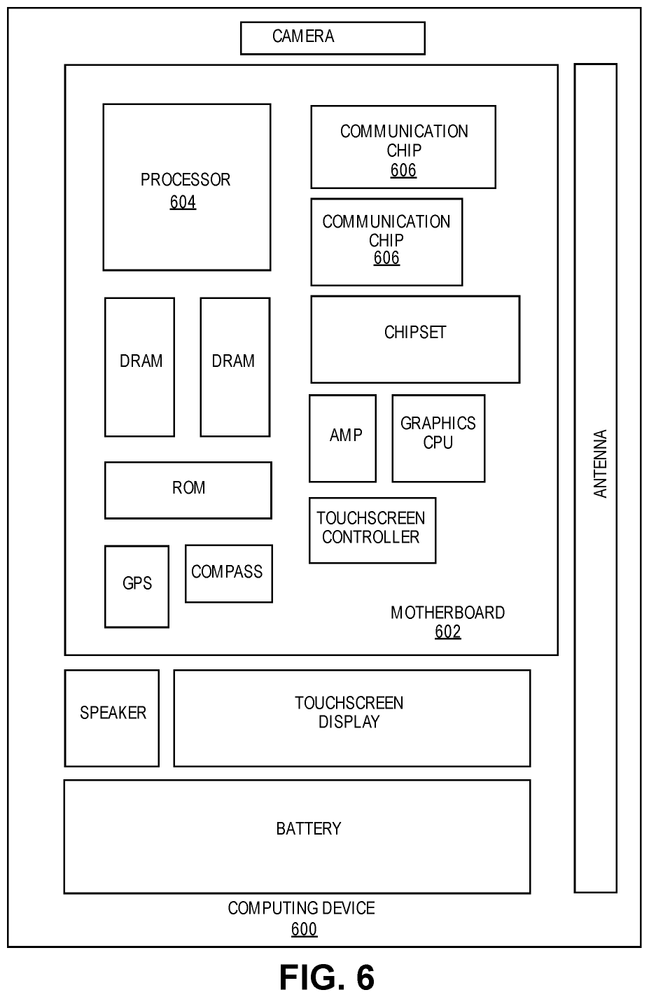

FIG. 6 illustrates a computing device 600 in accordance with one embodiment of the invention. The computing device 600 houses a board 602. The board 602 may include a number of components, including but not limited to a processor 604 and at least one communication chip 606. The processor 604 is physically and electrically coupled to the board 602. In some implementations the at least one communication chip 606 is also physically and electrically coupled to the board 602. In further implementations, the communication chip 606 is part of the processsor 604.

Depending on its applications, computing device 600 may include other components that may or may not be physically and electrically coupled to the board 602. These other components include, but are not limited to, volatile memory (e.g., DRAM), non-volatile memory (e.g., ROM), flash memory, a graphics processor, a digital signal processor, a crypto processor, a chipset, an antenna, a display, a touchscreen display, a touchscreen controller, a battery, an audio codec, a video codec, a power amplifier, a global positioning system (GPS) device, a compass, an accelerometer, a gyroscope, a speaker, a camera, and a mass storage device (such as hard disk drive, compact disk (CD), digital versatile disk (DVD), and so forth).

The communication chip 606 enables wireless communications for the transfer of data to and from the computing device 600. The term “wireless” and its derivatives may be used to describe circuits, devices, systems, methods, techniques, communications channels, etc., that may communicate data through the use of modulated electromagnetic radiation through a non-solid medium, The term does not imply that the associated devices do not contain any wires, although in some embodiments they might not. The communication chip 606 may implement any of a number of wireless standards or protocols, including but not limited to Wi-Fi (IEEE 802.11 family), WiMAX (IEEE 802.16 family), IEEE 802.20, long term evolution (LTE), Ev-DO, HSPA+, HSDPA+, HSUPA+, EDGE, GSM, GPRS, CDMA, TDMA, DECT, Bluetooth, derivatives thereof, as well as any other wireless protocols that are designated as 3G, 4G, 5G, and beyond. The computing device 600 may include a plurality of communication chips 606. For instance, a first communication chip 606 may be dedicated to shorter range wireless communications such as Wi-Fi and Bluetooth and a second communication chip 506 may be dedicated to longer range wireless communications such as GPS, EDGE, GPRS, CDMA, WiMAX, LTE, Ev-DO, and others.

The processor 604 of the computing device 600 includes an integrated circuit die packaged within the processor 604. In some implementations of embodiments of the invention, the integrated circuit die of the processor includes one or more arrays, such as an array of 1T-1R. cell 100, built in accordance with embodiments of the present invention. The term “processor” may refer to any device or portion of a device that processes electronic data from registers and/or memory to transform that electronic data into other electronic data that may be stored in registers and/or memory.

The communication chip 606 also includes an integrated circuit die packaged within the communication chip 606. In accordance with another implementation of an embodiment of the invention, the integrated circuit die of the communication chip includes RRAM memory arrays integrated into a logic processor, built in accordance with embodiments of the present invention.

In further implementations, another component housed within the computing device 600 may contain a stand-alone integrated circuit memory die that includes one or more arrays of 1T-1R cells 100, built in accordance with embodiments of the present invention.

In various implementations, the computing device 600 may be a laptop, a netbook, a notebook, an ultrabook, a smartphone, a tablet, a personal digital assistant (PDA), an ultra-mobile PC, a mobile phone, a desktop computer, a server, a printer, a scanner, a monitor, a set-top box, an entertainment control unit, a digital camera, a portable music player, or a digital video recorder. In further implementations, the computing device 600 may be any other electronic device that processes data.

Accordingly, one or more embodiments of the present invention relate generally to the fabrication of embedded microelectronic memory. The microelectronic memory may be non-volatile, wherein the memory can retain stored information even when not powered. One or more embodiments of the present invention relate to the fabrication of a 1T-1R cell 100. Such a 1T-1R cell 100 may be used in an embedded non-volatile memory.

Thus, embodiments of the present invention include an ambipolar layer based transistors for memory applications and methods of fabrication.

Example 1: A semiconductor device includes a transistor structure. The transistor structure further includes a semiconductor substrate. An insulator disposed above the substrate. An ambipolar layer is disposed on the insulator layer. A gate dielectric layer is disposed on the ambipolar layer. A gate electrode is disposed on the gate dielectric layer. A source region and a drain region are disposed on the ambipolar conductive layer. The source region is separated from the drain region by the gate electrode. A source contact is disposed on the source region and a drain contact is disposed on the drain region. A memory device is disposed on the drain contact.

Example 2: The semiconductor device of example 1, wherein the ambipolar layer includes a material selected from the group consisting of transition metal dichalcogenide, a carbon nanotube and a pentacene.

Example 3: The semiconductor device structure of example 1 or 2, wherein the ambipolar layer has a thickness between 0.2 nm-0.5 nm.

Example 4: The semiconductor device structure of example 1, wherein the source contact and the drain contact further include an adhesion layer on the ambipolar layer and a conductive fill layer on the adhesion layer.

Example 5: The semiconductor device structure of example 1, wherein the gate dielectric layer is a high-K gate dielectric layer.

Example 6: The semiconductor device structure of example 1 or 5, wherein the gate dielectric layer has a portion disposed on the sidewall of the gate electrode.

Example 7: A semiconductor device includes a transistor structure. The transistor structure includes a semiconductor substrate. An insulator is disposed on the substrate. A transition metal dichalcogenide (TMDC) layer is disposed on the insulator layer. A gate dielectric layer is disposed on the TMDC layer. A gate electrode is disposed on the gate dielectric layer. A source region and a drain region are disposed on the TMDC layer. The source region is separated from the drain region by the gate electrode. A source contact is disposed on the source region and a drain contact is disposed on the drain region. A resistive random access memory (RRAM) element is disposed on the drain contact. The RRAM device includes a bottom electrode. A switching layer is disposed above the bottom electrode and a top electrode is disposed above the switching layer.

Example 8: The semiconductor device of example 7, wherein the TMDC layer has a chemical composition, MX₂, where M is a transition metal and X is a chalcogen.

Example 9: The semiconductor device of example 8, wherein the transition metal, M, is selected from a group consisting of molybdenum, tungsten and chromium, and the chalcogen, X, is selected from a group consisting of sulfur, selenium and tellurium.

Example 10: The semiconductor device of example 7, wherein the TMDC layer has a thickness between 0.2-5 nm.

Example 11: The semiconductor device of example 7, wherein the gate dielectric layer is a high K gate dielectric layer.

Example 12: The semiconductor device of example 7 or 11, wherein the gate dielectric layer has a portion is disposed on sidewalls of the gate electrode,

Example 13: The semiconductor device of example 7, wherein the switching layer has a chemical composition, MO_{2-X}, where M is a metal and O is an oxide, where X is approximately in the range from 0 to 0.05.

Example 14: The semiconductor device of example 7 or 13, wherein the switching layer has a thickness approximately in the range of 1-5 nm and the oxygen exchange layer has a thickness approximately in the range of 5-20 nanometers.

Example 15: The semiconductor device of example 7, wherein the bottom electrode and the top electrode comprise a material selected from the group consisting of titanium nitride, tantalum nitride, tungsten and ruthenium.

Example 16: The semiconductor device of example 7, 13 or 14, wherein the oxygen exchange layer is disposed on the switching layer and below the top electrode.

Example 17: The semiconductor device of example 7, 13, 15 or 16, wherein the oxygen exchange layer is disposed on the bottom electrode and below the switching layer.

Example 18: A method of fabricating semiconductor structure includes providing a substrate. The method includes forming an insulator layer on the substrate. The method includes forming an ambipolar layer on the insulator layer. The method includes forming a gate dielectric layer on the ambipolar layer. A gate electrode is formed on the gate dielectric layer. A source region and a drain region are formed on the ambipolar layer. A source contact is formed on the source region and a drain contact is formed on the drain region. The source region is separated from the drain region by the gate electrode. The method further includes forming a resistive random access memory (RRAM) element on the drain contact. Forming the RRAM device includes forming a bottom electrode and forming a switching layer above the bottom electrode. A top electrode is disposed above the switching layer.

Example 19: The method of example 18, wherein the forming the ambipolar layer includes a process selected from the group consisting of an atomic layer deposition process, a thermally assisted growth process, and an exfoliation process.

Example 20: The method of example 18, wherein, forming the RRAM device further comprises forming an oxygen exchange layer on the switching layer.

Example 21: The method of example 18 or 20, wherein forming the RRAM device further includes forming a dielectric spacer laterally surrounding the switching layer and the top electrode.

Example 22: The method of example 18, 20 or 21, wherein, forming the RRAM device further comprises forming an oxygen exchange layer on the bottom electrode.

Example 23: The method of example 20, wherein the top electrode layer is formed on the oxygen exchange layer without an air break post deposition of the oxygen exchange layer.

What is claimed is:

1. A semiconductor device comprising:
a transistor structure, the transistor structure comprising:
a semiconductor substrate;
an insulator disposed above the substrate;
an ambipolar layer disposed on the insulator layer;
a gate dielectric layer disposed on the ambipolar layer;
a gate electrode disposed on the gate dielectric layer;
a source region and a drain region disposed on the ambipolar conductive layer, the source region separated from the drain region by the gate electrode;
a source contact disposed on the source region and a drain contact disposed on the drain region; and
a memory device disposed on the drain contact.

2. The semiconductor device of claim 1, wherein the ambipolar layer includes a material selected from the group consisting of transition metal dichalcogenide, a carbon nanotube and a pentacene.

3. The semiconductor device structure of claim 1, wherein the ambipolar layer has a thickness between 0.2 nm-0.5 nm.

4. The semiconductor device structure of claim 1, wherein the source contact and the drain contact further include an adhesion layer on the ambipolar layer and a conductive fill layer on the adhesion layer.

5. The semiconductor device structure of claim 1, wherein the gate dielectric layer is a high-K gate dielectric layer.

6. The semiconductor device structure of claim 1, wherein the gate dielectric layer has a portion disposed on the sidewall of the gate electrode.

7. A semiconductor device comprising:
a transistor structure comprising:
a semiconductor substrate;
an insulator disposed on the substrate;
a transition metal dichalcogenide (TMDC) layer disposed on the insulator layer;
a gate dielectric layer disposed on the TMDC layer;
a gate electrode disposed on the gate dielectric layer,
a source region and a drain region disposed on the TMDC layer, the source region separated from the drain region by the gate electrode;
a source contact disposed on the source region and a drain contact disposed on the drain region;
a resistive random access memory (RRAM) element disposed on the drain contact, the RRAM device comprising:
a bottom electrode;
a switching layer disposed above the bottom electrode; and
a top electrode disposed above the switching layer.

8. The semiconductor device of claim 7, wherein the TMDC layer has a chemical composition, MX₂, where M is a transition metal and X is a chalcogen.

9. The semiconductor device of claim 8 where the transition metal, M, is selected from a group consisting of molybdenum, tungsten and chromium, and the chalcogen, X, is selected from a group consisting of sulfur, selenium and tellurium.

10. The semiconductor device of claim 7, wherein the TMDC layer has a thickness between 0.2-5 nm.

11. The semiconductor device of claim 7, wherein the gate dielectric layer is a high K gate dielectric layer.

12. The semiconductor device of claim 7, wherein the gate dielectric layer has a portion disposed on sidewalls of the gate electrode.

13. The semiconductor device of claim 7, wherein the switching layer has a chemical composition, MO_{2-X}, where M is a metal and O is an oxide, where X is approximately in the range from 0 to 0.05.

14. The semiconductor device of claim 7, wherein the switching layer has a thickness approximately in the range of 1-5 nm and the oxygen exchange layer has a thickness approximately in the range of 5-20 nanometers.

15. The semiconductor device of claim 7, wherein the bottom electrode and the top electrode comprise a material selected from the group consisting of titanium nitride, tantalum nitride, tungsten and ruthenium.

16. The semiconductor device of claim 7, wherein an oxygen exchange layer is disposed on the switching layer and below the top electrode.

17. The semiconductor device of claim 7, wherein the oxygen exchange layer is disposed on the bottom electrode and below the switching layer.

18. A method of fabricating semiconductor structure, the method comprising:
providing a substrate;
forming an insulator layer on the substrate;
forming an ambipolar layer on the insulator layer;
forming a gate dielectric layer on the ambipolar layer;
forming a gate electrode on the gate dielectric layer;
forming a source region and a drain region on the ambipolar layer;
forming a source contact on the source region and forming a drain contact on the drain region, the source region separated from the drain region by the gate electrode;
forming a resistive random access memory (IMAM) element on the drain contact, the forming the RRAM device comprising:
forming a bottom electrode;
forming a switching layer above the bottom electrode; and
a top electrode disposed above the switching layer.

19. The method of claim 18, wherein the forming the ambipolar layer comprises a process selected from the group consisting of an atomic layer deposition process, a thermally assisted growth process, and an exfoliation process.

20. The method of claim 18, wherein, forming the RRAM device further comprises forming an oxygen exchange layer on the switching layer.

21. The method of claim 18, wherein, forming the RRAM device further comprises forming an oxygen exchange layer on the bottom electrode.

22. The method of claim 18, wherein forming the RRAM device further comprises forming a dielectric spacer laterally surrounding the switching layer and the top electrode.

23. The method of claim 20, wherein the top electrode layer is formed on the oxygen exchange layer without an air break post deposition of the oxygen exchange layer.
